(19) United States
(12) Patent Application Publication
(10) Pub. No.: US 2009/0302873 A1
(43) Pub. Date: Dec. 10, 2009

(54) System for electrochemically measuring an analyte in a sample material

(75) Inventors: Barry Haggett, Luton (GB); Brian Birch, Higham Ferrers (GB); Roberto Andres, Luton (GB); Damian Edward Haydon Baskeyfield, Auldearn (GB)

Correspondence Address: PHILIP S. JOHNSON;JOHNSON & JOHNSON, ONE JOHNSON & JOHNSON PLAZA, NEW BRUNSWICK, NJ, 08933-7003, US

(73) Assignee: LifeScan Scotland Limited, Inverness (GB)

(21) Appl. No.: 12/447,475

(22) Filed: Aug. 21, 2009

Related U.S. Application Data
(62) Division of application No. PCT/GB2007/003340, filed on Sep. 5, 2007.

(51) Int. Cl. G01R 27/08

(52) U.S. Cl. 324/724

(57) ABSTRACT

Strips, particularly test strips and adapters for test strips, for use in meters for the electrochemical measurement of analyte in a sample material and in particular the glucose concentration of a sample of blood. The strips comprise a plurality of working connectors, for interfacing with the meter, coupled to one or more working electrodes. The strips are of particular use in adapting multi-input meters for single input use.

### FIELD OF THE INVENTION

The present invention relates to strips for use with multi-input meters for the electrochemical measurement of analyte in a sample material. In particular, the invention relates to test strips and adapters for test strips for determining glucose concentration in samples of blood.

### BACKGROUND OF THE INVENTION

Devices for measuring blood glucose levels are invaluable to diabetics—especially devices that may be used by the sufferers themselves, enabling them to monitor their own glucose levels and take doses of insulin.

Conventionally, at least the part of the glucose-measuring device that comes into contact with the blood sample is disposable. This is important for reasons of hygiene, ease of use, the avoidance of cross-contamination between samples, and to prevent the spread of infectious diseases. Since diabetics must frequently check their glucose levels, it is important that the cost of the disposable is minimised.

Current glucose measuring devices favour an electrochemical measurement method over colorimetric methods. The general principle is that an electric current is measured between two sensor parts called the working and reference sensor parts respectively. The working sensor part includes at least one working electrode onto which is applied a layer of enzyme reagent, comprising an enzyme such as the flavo-enzyme glucose oxidase and an electron mediator compound such as ferricyanide. When a potential difference is applied across the electrodes, a current is generated by the transfer of electrons from the substance being measured (the enzyme substrate), via the enzyme and to the surface of the working electrode. The measurement of glucose using a glucose oxidase and ferricyanide test strip is based upon the specific oxidation of glucose by the glucose oxidase. During this reaction, the glucose oxidase becomes reduced. The enzyme is re-oxidized by reaction with the ferricyanide, which is itself reduced during the course of the reaction. When these reactions are conducted with a potential difference applied between the reference and working electrodes, an electrical current may be created by the electrochemical re-oxidation of the reduced mediator ion (ferrocyanide) at the working electrode surface. Thus, since the amount of ferrocyanide created during the chemical reaction described above is directly proportional to the amount of glucose in the sample positioned between the electrodes, the current generated is proportional to the glucose content of the sample. The current generated is also proportional to the area of the working electrode. Given a known area of the working sensor part, the glucose concentration can therefore be determined from the measured electric current.

Because it can be very important to know the concentration of glucose in blood, particularly for people with diabetes, meters have been developed using the principles set forth above to enable a user to sample and test their blood to determine the glucose concentration at any given time. The generated current is monitored by the meter and converted into a reading of glucose concentration using an algorithm that relates current to glucose concentration via a simple mathematical formula. In general, the meters work in conjunction with a disposable strip that includes a sample chamber and at least two sensor parts disposed within the sample chamber in addition to the enzyme (e.g. glucose oxidase) and mediator (e.g. ferricyanide). A suitable disposable electrochemical test strip is that used in the OneTouch (RTM) Ultra(RTM) whole blood testing kit, which is available from LifeScan, Inc. In use, the user pricks their finger or other convenient site to induce bleeding and introduces a blood sample to the sample chamber, thus starting the chemical reaction set forth above.

In electrochemical terms, the function of the meter is two fold. Firstly, it provides a polarizing voltage (approximately +0.4 V in the case of OneTouch (RTM) Ultra(RTM)) that polarizes the electrical interface and leads to current flow at the working electrode surface. Secondly, it measures the current that flows in the external circuit between the anode (working electrode) and the cathode (reference electrode).

The meter described above may be considered a simple electrochemical system that operates in two-electrode mode. However, in practice, third and even fourth electrodes may be used to facilitate the measurement of glucose and/or to perform other functions in the meter. In particular, multi-input meters for use with electrochemical test strips that have two or more working electrodes are commonly used. It is also known to provide a cell having both a reference electrode and a counter electrode in which the counter electrode serves to carry the current flowing through the cell.

U.S. Pat. No. 6,733,655 describes a device for measuring the concentration of a substance in a sample liquid, said device comprising a reference sensor part, a first working sensor part for generating charge carriers in proportion to the concentration of said substance in the sample liquid; and a second working sensor part also for generating charge carriers in proportion to the concentration of said substance in the sample liquid. Thus it will be seen that in accordance with the aforementioned U.S. patent that the measuring device compares the current passed by two working sensor parts as a result of their generation of charge carriers and gives an error indication if the two currents are too dissimilar—i.e. the current at one sensor part differs too greatly from what would be expected from considering the current at the other.

It is not always necessary or desirable to use test strips with more than one working electrode. However, multi-input meters are often not backwards compatible with dual electrode (i.e. single reference electrode and single working electrode) test strips. A multi-input meter with an unconnected second working sensor input may interpret lack of an input as an erroneous measurement and indicate an error in the test strip. Similarly, the sensor parts of an electrochemical test strip must be matched to the meter used in order for an accurate measurement to be made, since the calculation performed by the meter to determine glucose concentration is dependent upon certain assumed information concerning the expected test strip (e.g. the working surface area of the electrodes).

The restriction that a meter can only be used with particular test strips that have configurations that are matched to that meter is inconvenient to a user, who is consequently forced to use only those test strips. Thus, a user who has recently replaced his existing single working sensor meter with a multi-input meter may find that his supply of single working electrode test strips for use with his previous meter are not compatible with the multi-input meter and must be discarded and replaced with new multiple sensor test strips. Equally, a user may not always be able to obtain test strips that are designed specifically for his meter, although test strips designed for different meters may be available to him. Applicants recognize that it is desirable that the user should be able to use test strips with his meter when the test strips are not designed specifically (i.e. matched to) his meter.

The provision of multiple working sensors on a test strip adds to the test strip's complexity and therefore also to the cost and difficulty of its manufacture. It is also to be expected that manufacturing defects will be more common in test strips of greater complexity. Since multiple working sensors are not required for all applications it is desirable that a user has the option of using a single working sensor test strip with any meter. However, if a multi-input meter is used, the lack of backwards compatibility with single working sensor test strips forces the user to use the more complex multiple working sensor test strips, even if they are not required for his application.

Finally, the presence of multiple working sensors is problematic in cases where only a very limited quantity of sample material (e.g. blood) is available. In such cases, sufficient material may be present to fully complete the circuit in test strip having a single working electrode, but not a test strip having multiple working electrodes (all of which need to be covered by the sample material). Therefore, the lack of compatibility between multi-input meters and single working electrode test strips inhibits the use of test strips that are better suited for certain applications.

Applicants have recognized that it would be desirable to permit the user of a multi-input glucose meter to use a test strip having electrodes that are not necessarily matched to the meter.

### SUMMARY

The present invention includes a strip for use with a multi-input meter for the electrochemical measurement of analyte in a sample material, a system of a strip with a meter, and a method of manufacturing such a strip. In one embodiment, the strip includes: a reference electrode; at least one working electrode; a reference connector and a plurality of working connectors for interfacing the strip to the meter; a reference link electrically coupling the reference electrode to the reference connector; and a plurality of working links electrically coupling the at least one working electrode to the plurality of working connectors, and characterised in that at least one working electrode is coupled to a plurality of the working connectors.

Coupling working electrodes to multiple working connectors enables a single working electrode (or a single group of interconnected working electrodes) to provide current to more than one of the working connectors (via the plurality of working links). On connection of the strip to a multi-input meter, the total current supplied by the electrodes will be split between the working links and therefore also between the connectors. Thus, the working electrode will appear to the meter to be a plurality of electrodes, with a different one of the plurality connected to each working connector. In this way, the strip enables a multi-input meter to be used with fewer working electrodes than are normally required by the meter.

Another advantage of sharing working electrodes between multiple connectors is that the total current supplied to each input of the meter will be attenuated as a function of the number of inputs interfaced to the connectors. This approach permits an otherwise inappropriately large current to be split between inputs that are configured to accept a lower current.

The use of a strip according to the invention allows different configurations of working electrodes to be used with meters that are not specifically designed for those configurations. Particularly advantageously, no modification of the comparatively expensive and complex meter is required, instead all that is required is a modification of the test strip. Such modification may be performed by adapting the test strip manufacturing process in order to manufacture strips according to the present invention, or by modification of existing electrochemical test strips. For example, a strip according to certain embodiments of the present invention could be manufactured by modifying an existing multi-input test strip by adding junctions between selected working links. The modification may further include forming discontinuities in selected working links.

The strip of the present invention is preferably an electrochemical test strip where, in use, the reference and working electrodes contact the sample material. Alternatively, the strip may be an adapter strip for connection between a prior art test strip and a meter. In the adapter embodiment, the reference and working electrodes mate, when in use, with the reference and working connectors of the test strip. The use of such an adapter advantageously permits existing (and unmodified) single or multiple working electrode test strips to be used with multi-input meters without modification of the test strip itself Since the adapter does not contact the sample material, it is reusable.

The at least one of the working electrodes may be coupled to all of the working connectors.

The plurality of working links may have the same resistance, splitting the total current equally between the working connectors. Alternatively, the plurality of working links may have different resistances, allowing the distribution of current between the working connectors to be weighted.

The one or more of the plurality of working links may have an overlay material over at least a portion of the one or more of the plurality of working links which decreases the electrical resistance of the one or more of the plurality of working links.

The overlay material may include a single layer of an overlay material. Alternatively, it may be formed of several layers of the same or different materials.

To control the distribution of current between the working connectors, the plurality of working links may all be made of material having the same or different resistivities and the working links may also have the same or different width, length, thickness and layout.

A plurality of the working electrodes may be overlaid with an overlay material, the overlay material electrically intercoupling the overlaid working electrodes. The overlay material may entirely cover the working surfaces of the overlaid working electrodes, or it may only partially cover the working surfaces of the overlaid working electrodes.

Overlaying the electrodes is advantageous since it can be used to simply convert a prior art test strip into a strip according to the present invention. In embodiments where the entire working surface of the working electrodes (i.e. the entire surface that would otherwise be exposed to the sample material) is overlaid, overlaying with a different material to that of the working electrode can be used to present a working surface to the sample that has different electrical, chemical and physical properties. What is more, the overlay material may substantially cover gaps located between adjacent overlaid working electrodes. Covering these gaps effectively enlarges the working surface of the electrodes, increasing the current that flows through the electrode.

Overlaying the working electrodes thus enables the area and material of existing working electrodes' effective working surfaces to be altered in addition to providing interconnection of the working electrodes (and thus also the working links). Overlaying is therefore particularly useful in modifying existing test strips for use with meters having input requirements that are not compatible with the unmodified test strips.

Optionally, the overlay material may be a carbon ink. Carbon inks are suitable for screen printing, facilitating the large-scale automated modification of prior art test strips.

At least one of the plurality of working links may be a split link, the split link comprising a first link portion having a first resistance and being formed of material having a first resistivity, electrically coupled to a second link portion having a second resistance and being formed of material having a second resistivity. The first and second resistivities may be different. The split link may further comprise a third link portion, wherein: the first and third link portions are separated by a gap; and the second portion at least partially overlays each of the first and third link portions such that the gap is bridged, electrically intercoupling the first and third link portions. The third link portion may be formed of material having the first resistivity.

In some embodiments a plurality of the working links are split links. The plurality of split links may share the same first resistivities and may or may not share the same second resistivities.

The use of a split link permits the resistance of the working links to be varied in order to apply a desired level of attenuation for each link. By selecting materials of appropriate resistivity, the resistance of each working link can be made equal, dividing the current equally between them, or can alternatively be weighted in order to weight the distribution of current between them.

The formation of split links as first and third link portions, separated by a gap with a second portion bridging the gap, facilitates the strips' manufacture. Large numbers of identical strip ‘blanks’ can be manufactured with only the first and third link portions in place, with the subsequent second link portion added at a later stage to bridge the first and third link portions, which can be accomplished by a suitable technique, such as, for example, by screen printing. Selecting materials of appropriate resistivities for the third link portions allows the easy customisation of a strip ‘blank’ into a strip adapted for a particular meter. Since this process of customisation is simply the overlaying of material to form the bridging second link portions, it is well suited for low-volume manufacturing methods.

A plurality of split links may couple at least one working electrode to a plurality of working connectors via a junction, where the second link portions of the split links are located between the junction and the working connectors. Positioning the second link portions at the connector side of the junction permits a different weighting to be applied (through selection of appropriate second link portion materials) to the current available at each of the working connectors.

In embodiments that use a counter electrode that is separate to the reference electrode, a counter electrode is provided and coupled to a counter connector using a counter link.

In another aspect, a method of manufacturing a strip for use with a multi-input meter for the electrochemical measurement of analyte in a sample material is provided. The method includes providing a reference electrode; providing at least one working electrode; providing a reference connector and a plurality of working connectors for interfacing the strip to the measuring device; electrically coupling the reference electrode to the reference connector using a reference link; and electrically coupling the at least one working electrode to the plurality of working connectors using a plurality of working links, and characterised in that electrically coupling the at least one working electrode to the plurality of working connectors includes coupling at least one working electrode to a plurality of the working connectors.

In another aspect, a system for electrochemically measuring an analyte in a sample material is provided. The system includes a strip including: a reference electrode and a working electrode, a reference connector, a first working connector, and second working connector for interfacing the strip to the measuring device; a reference link configured to electrically couple the reference electrode to the reference connector; a first working link configured to electrically couple the working electrode to the first working connector, and a second working link configured to electrically couple the working electrode to the second working connector, and a meter comprising: a first test voltage circuit capable of applying a first test voltage between the first working connector and the reference connector; a second test voltage circuit capable of applying a second test voltage between the second working connector and the reference connector; a current measurement circuit capable of measuring a first test current between the first working connector and the reference connector and a second test current between the second working connector and the reference connector.

These and other embodiments, features and advantages will become apparent to those skilled in the art when taken with reference to the following more detailed description of the invention in conjunction with the accompanying drawings that are first briefly described.

### BRIEF DESCRIPTION OF THE DRAWINGS

The accompanying drawings, which are incorporated herein and constitute part of this specification, illustrate presently preferred embodiments of the invention, and, together with the general description given above and the detailed description given below, serve to explain features of the invention (wherein like numerals represent like elements), of which:

FIG. 1 shows a prior art test strip having two working electrodes;

FIG. 2 shows the prior art test strip of FIG. 1 partially covered by a dielectric mask;

FIG. 3 shows a test strip according to a preferred embodiment having two working links and connectors;

FIG. 4 shows a test strip according to a preferred embodiment having three working links and connectors;

FIG. 5 shows the test strip of FIG. 3 covered by a dielectric mask;

FIG. 6 shows a circuit diagram of a portion of a test strip according to a preferred embodiment.

FIG. 7 shows a test strip according to a preferred embodiment wherein the working electrodes have been overlaid with an overlay material;

FIG. 8 shows an adapter according to a preferred embodiment and a prior art test strip having a single working electrode;

FIG. 9 shows an adapter according to a preferred embodiment and a prior art test strip having two working electrodes;

FIG. 10 shows an adapter according to a preferred embodiment having split working links, and a prior art test strip having a single working electrode; and

FIG. 11 shows a test strip according to a preferred embodiment having two working electrodes and split working links.

### DESCRIPTION OF THE PREFERRED EMBODIMENTS

The following detailed description should be read with reference to the drawings, in which like elements in different drawings are identically numbered. The drawings, which are not necessarily to scale, depict selected exemplary embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used herein, the terms “about” or “approximately” for any numerical values or ranges indicate a suitable dimensional tolerance that allows the part or collection of components to function for its intended purpose as described herein.

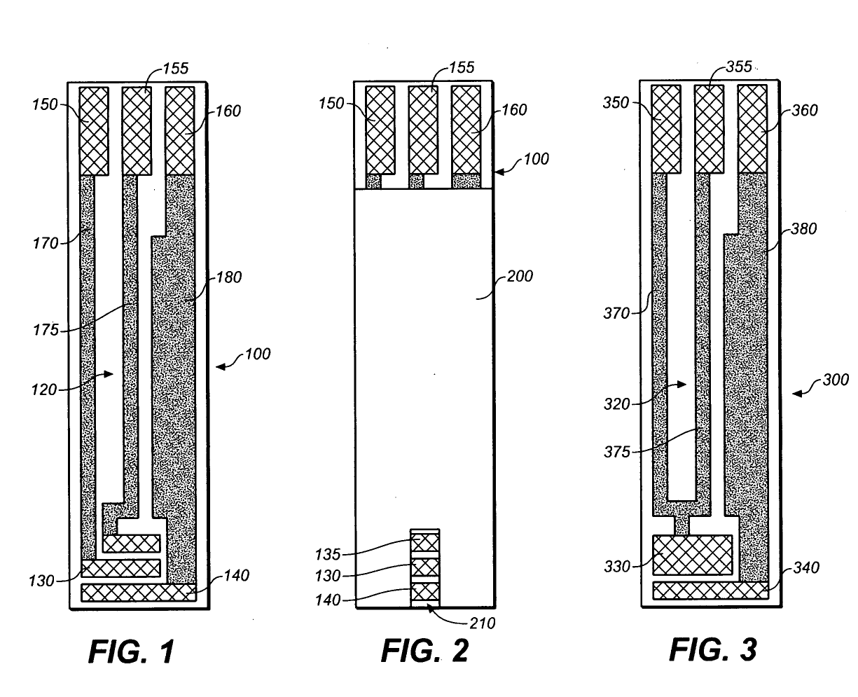

FIG. 1 shows a prior art test strip 100, comprising a dielectric substrate 120 upon which are provided first and second working electrodes 130, 135, a reference electrode 140, first and second working connectors 150, 155, and a reference connector 160. First and second working links 170, 175 connect the first and second working electrodes 130, 135 to the first and second working connectors 150, 155, respectively, and a reference link 180 connects the reference electrode 140 to the reference connector 160.

In the context of this application, ‘dielectric’ is used to describe a substrate that has suitable electrically insulating properties.

FIG. 2. shows the prior art test strip of FIG. 1 with a dielectric mask layer 200 applied to prevent exposure of the working and reference links 170, 175, 180 to sample material. The mask 200 defines a window 210 that exposes a working surface of the working and reference electrodes 130, 135, 140 in order that they can be contacted by sample material.

An enzyme layer (not shown) is printed over the mask 200 and thus also onto the areas of the electrodes 130, 135, 140 that are exposed through the window 210 in the mask 200, forming the reference sensor part and the two working sensor parts, respectively. A layer of adhesive is then printed onto the strip and a hydrophilic film is laminated onto the strip and held in place by the adhesive. The film defines a sample chamber over the exposed sensor parts and a thin channel to draw liquid sample material into the sample chamber by capillary action. Finally, a protective plastic cover tape is applied over the hydrophilic film, the cover tape including a transparent portion over the sample chamber. The transparent portion enables a user to tell instantly if a strip has been used and also assists in affording a visual check as to whether enough sample material has been applied.

In use, the test strip 100 is inserted into a meter (not shown). The meter includes a set of contacts that electrically couple with the working and reference connectors 150, 155, 160 on insertion. The meter applies a potential difference across the reference connector 160 and each of the two working connectors 150, 155 and, after a predetermined period of time, the electric current flowing though each of the working connectors 150, 155 (and therefore also through the working electrodes 130, 135) is measured by the meter and the two measurements are compared. If the measurements differ by more than a threshold amount, an error message is displayed on the meter and the test must be repeated. However, if the measurements do not differ by more than the threshold amount, a glucose level is calculated based on the measured currents and displayed on the meter.

FIG. 3 shows a test strip 300 according to a preferred embodiment. The test strip 300 includes a substrate 320 that may be made of any dimensionally stable dielectric material that is resistant to the sample material. Preferred materials for the substrate include polyester, polycarbonate, polyamide, polyethylene, polypropylene, polyvinylchloride and nylon. Other suitable materials include plastics, ceramics and glass. The test strip 300 further includes a first working electrode 330, a reference electrode 340, two working connectors 350, 355 and a reference connector 360. The first working electrode is electrically coupled to each of the working connectors 350, 355 by a working link 370, 375 and the reference electrode 340 is electrically coupled to the working connector 360 by a reference link 380. Suitable materials for the electrodes 330, 340, connectors 350, 355, 360 and links 370, 375, 380 include carbon, gold, platinum, palladium, iridium, rhodium, conducting polymers, stainless steel and doped tin oxide. The electrodes 330, 340, connectors 350, 355, 360 and links 370, 375, 380 may be, but are not necessarily, of the same material. Preferably, the electrodes 330, 340, connectors 350, 355, 360 and links 370, 375, 380 are formed by screen printing carbon ink printed onto the substrate 320.

Although only a single working electrode 330 is shown in FIG. 3, the test strip 300 may further comprise additional working electrodes, either electrically coupled to or isolated from the first working electrode 330. Similarly, the test strip 300 may further comprise additional working connectors and working links, either electrically coupled to or isolated from those shown in FIG. 3. By way of example, FIG. 4 shows a test strip 400 according to a preferred embodiment that has three working connectors 350, 355, 456 and three working links 370, 375, 476 coupling the working connectors 350, 355, 456 to a single working electrode 330.

FIG. 5 shows the test strip 300 of FIG. 3 with a dielectric mask layer 500 applied to prevent exposure of the working and reference links 370, 375, 380 to sample material. The mask 500 defines a window 510 that exposes a working surface of the working and reference electrodes 330, 340 in order that they can be contacted by sample material. The mask may be formed of any suitable dielectric material that is resistant to the sample material. Preferably, for ease of manufacture, the mask is screen printed onto the test strip.

An enzyme layer (not shown) is printed over the mask 500 and thus also onto the portions of the electrodes 330, 340 that are exposed through the window 510 in the mask 500, forming the reference sensor part and working sensor part, respectively. A layer of adhesive is then printed onto the strip and a hydrophilic film is laminated onto the strip and held in place by the adhesive. The film defines a sample chamber over the exposed sensor parts and a thin channel to draw liquid sample material into the sample chamber by capillary action. Finally, a protective plastic cover tape is applied over the hydrophilic film, the cover tape including a transparent portion over the sample chamber. The transparent portion enables a user to tell instantly if a strip has been used and also assists in affording a visual check as to whether enough sample material has been applied.

When the test strip 300 of FIGS. 3 and 5 is used with a multi-input meter, the current flowing between the reference and working electrodes 340, 330 is split between the working links 370, 375 connected to the working electrode 330 and thus also between the working connectors 350, 355. If the working links 370, 375 have equal resistance and if equal voltages are applied, the current measured at each of the working connectors 350, 355 will be half of the current flowing between the reference and working electrodes 340, 330. Since an equal current is measured at each of the electrodes, the multi-input meter will not detect an error.

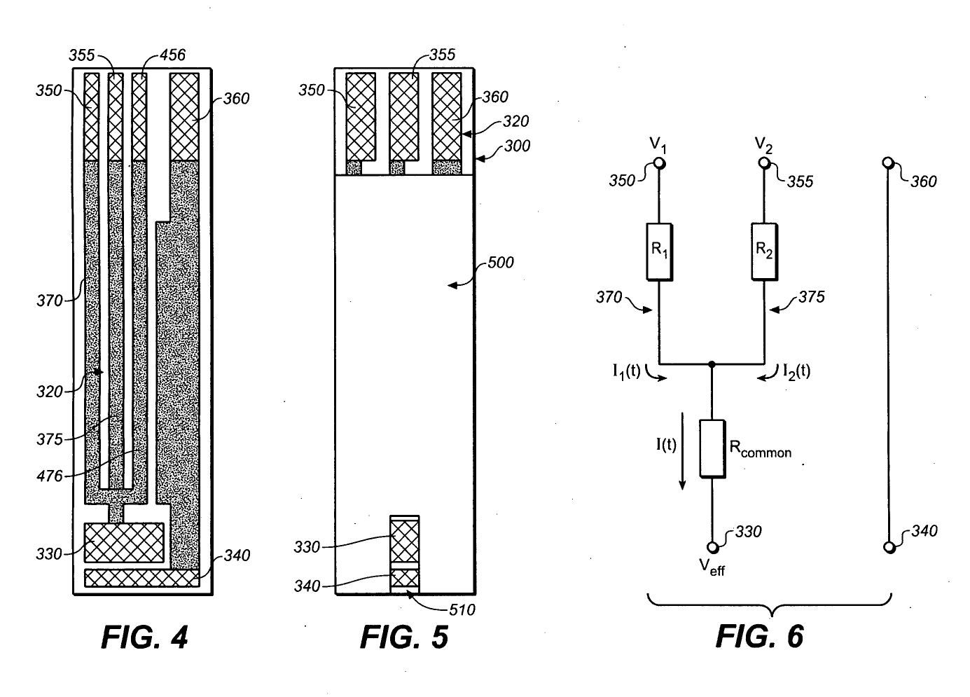

In one embodiment, a meter may apply a first test voltage V₁ between first working connector 350 and reference connector 360, and a second test voltage V₂ between the second working connector 355 and the reference connector 360, as illustrated in FIG. 6. As a result of first test voltage V₁ and second test voltage V₂, the meter can measure a first test current I₁(t) and a second test current I₂(t) that are both proportional to an analyte concentration. The terms I₁(t) and I₂(t) represents the first and second test currents, respectively, as a function of time t.

As show below, Equation 1 can be derived by applying Kirchoff's current law to the circuit illustrated in FIG. 6:

I(t)=I₁(t)+I₂(t) Eq. 1.

In one embodiment, the first test voltage V₁ and second test voltage V₂ may be exactly the same in magnitude. However, in practice, the first test voltage V₁ and second test voltage V₂ may have a finite difference in magnitude because of the variability typically observed in electronic components. A difference voltage V_{diff} is a difference between the first test voltage V₁ and the second test voltage V₂. As a result of the application of the first test voltage V₁ and second test voltage V₂, the difference voltage V_{diff} is effectively applied between the first working connector 350 and the second working connector 355. The following will describe the effects of V_{diff} on the current flow in the circuit of FIG. 6 before and after a liquid sample has been applied to the sensor.

For the first situation where a sample has not been applied to the sensor, I(t) is zero, hence from Eq. 1 the currents through both branches are equal in magnitude and opposite in direction I₁(t)=−I₂ (t). The magnitude of the current Iₛₕᵤₙₜ that flows between the first working connector 350 and the second working connector 355, as a result of the difference voltage V_{diff}, is directly proportional to the difference voltage V_{diff}, and inversely proportional to a shunt resistance Rₛₕᵤₙₜ between the first working connector 350 and the second working connector 355, as illustrated in Equation 2.

$$\vert {I}_{shunt} \vert = \frac{\vert {V}_{diff} \vert}{{R}_{shunt}} = \frac{\vert {V}_{2} - {V}_{1} \vert}{{R}_{shunt}} \qquad Eq . 2$$

The shunt resistance Rₛₕᵤₙₜ may include a summation of resistance values from the first working connector 350, first working link 370, second working link 375, and the second working connector 355. A simplified representation of Rₛₕᵤₙₜ is illustrated in FIG. 6 where the first working connector 350 and the second working connector 355 are both assumed to have a negligible resistance so that Rₛₕᵤₙₜ=R₁+R₂. In the preferred embodiment, the two resistors R₁ and R₂ will have about the same value hence:

$${R}_{1} = {R}_{2} = \frac{{R}_{shunt}}{2} \qquad Eq . 3$$

For the second situation where sample has been applied, I(t) is different from zero and hence there will be a voltage drop across R_{common}, R₁ and R₂. Hence the effective voltage V_{eff} applied to the electrode is:

V_{eff}=Vₛₕᵤₙₜ−I(t)R_{common} Eq. 4

Since Vₛₕᵤₙₜ is the voltage at the junction, as illustrated in FIG. 6, Equation 5 can be constructed:

Vₛₕᵤₙₜ=V₁−I₁(t)R=V₂−I₂(t)R₂ Eq. 5

and since V₁ and V₂ are similar then each can be substituted by the nominal polarisation potential, Vₚₒₗ, and since I₁(t) and I₂(t) are very similar, each can be substituted by I(t)/2 as derived from Eq. 1. Then, Eq. 5 becomes:

$${V}_{shunt} = {V}_{pol} - \frac{I ( t )}{2} \frac{{R}_{shunt}}{2} = {V}_{pol} - \frac{I ( t ) {R}_{shunt}}{4} \qquad Eq . 6$$

Substituting Vₛₕᵤₙₜ from Eq. 6 into the expression for V_{eff} (Eq. 4) results in Equation 7.

$$\begin{matrix}{V}_{eff} = {V}_{pol} - \frac{I ( t ) {R}_{shunt}}{4} - I ( t ) {R}_{common} \\ = {V}_{pol} - I ( t ) ( \frac{{R}_{shunt}}{4} + {R}_{common} )\end{matrix} \qquad Eq . 7$$

Hence, to ensure proper operation of the sensor, V_{eff} has to be sufficiently unattenuated by the terms in brackets in Eq. 7. Thus, Rₛₕᵤₙₜ and R_{common} must be sufficiently small in magnitude so that V_{eff} can allow an accurate measurement of analyte.

However, Rₛₕᵤₙₜ must also be sufficiently large in magnitude so that Iₛₕᵤₙₜ is sufficiently small (see Equation 2). If Iₛₕᵤₙₜ is sufficiently large (e.g., greater than pre-determined thresholds stored in the memory of the meter), an error message may be outputted by the glucose meter incorrectly identifying the strip as defective or as already used. For example, a pre-determined threshold may be about 100 nanoamperes. Accordingly, Rₛₕᵤₙₜ must also be sufficiently large in magnitude to prevent the meter from outputting an error message, but also must be sufficiently small in magnitude to allow for an accurate measurement of analyte.

As there is a compromise between the requirements for Rₛₕᵤₙₜ, it has to be determined for suitability. The first step in the determination is: as Rₛₕᵤₙₜ and R_{common} are dependant on the position of the junction and from Eq. 2, R_{common} will not contribute to increase Iₛₕᵤₙₜ and from Eq. 7 R_{common} on has 4 times more effect than Rₛₕᵤₙₜ: the solution is to move the junction as close as possible to the working electrode to achieve a maximum value of Rₛₕᵤₙₜ while a minimum contribution from R_{common}.

The second step in the determination process is: determine the maximum possible value of the difference |V2−V1| and configure Rₛₕᵤₙₜ to be a value slightly larger than the result of dividing this voltage difference by the value of the largest current for which the system does not detect the strip as defective or already used. Thus, in an embodiment of this invention, a lower limit for Rₛₕᵤₙₜ may be configured so that the resulting current Iₛₕᵤₙₜ is lower than the pre-determined error thresholds of the meter.

The third step in the determination process: determine a maximum possible I(t) value and configure both Rₛₕᵤₙₜ and R_{common} so that V_{eff} is not sufficiently decreased to cause an inaccurate glucose measurement. Note that maximum values for I(t) may be estimated at a high glucose concentration (e.g., 600 mg/dL), a low hematocrit level (e.g., 20%), a high temperature (40 degrees Celsius), or a combination thereof. Thus, in an embodiment of this invention, an upper limit for Rₛₕᵤₙₜ and R_{common} may be configured so that V_{eff} is not decreased by more than, for example, about 20% of the original value of Vₚₒₗ.

The dimensions of the working area of the electrodes 330, 340 exposed through the window 510 in the mask layer 500 may be adjusted to account for the fact that the current measured at each of the working connectors 350, 355 is less than the total current flowing between the reference and working electrodes, as illustrated in FIG. 5. Increasing the working area of the electrodes 330, 340 will increase the measured currents and decreasing their working area will decrease the measured current. Alternatively, a correction to the measured current may be applied at the meter or may be applied to the reading displayed by the meter (e.g. manually).

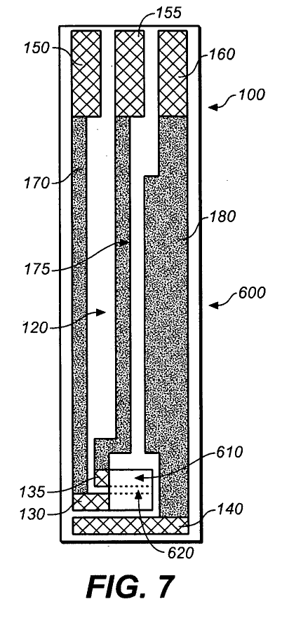

FIG. 7 shows the prior art test strip 100 of FIG. 1 modified to provide a test strip 600 according to a preferred embodiment. This modification includes overlaying the working electrodes 130, 135 and bridging the gap 620 between them with an electrically conductive overlay material 610. The overlay material 610 may be applied to the working electrodes 130, 135 and substrate 120 by any suitable method, for example by hand painting, but is preferably applied by screen printing a carbon ink onto the prior art test strip 100. Electrically coupling the working electrodes 130, 135 by bridging the gap 620 between them with the overlay material 610 has the effect of electrically coupling the working links 170, 175 through the bridged working electrodes 130, 135 and the current flowing between the reference electrode 140 and working electrodes 130, 135 is therefore split between the working links 170, 175 and therefore also between the working connectors 150, 155.

The total current flowing through the reference electrode 140 and the working electrodes 130, 135 of the test strip 600 of FIG. 7 can be adjusted by varying the effective working area of the working electrodes 130, 135. The working electrodes' 130, 135 effective working area can be increased by extending the overlay material 610 over areas of the substrate 120 that will be exposed to the sample material. In particular, bridging the gap 620 between the working electrodes 130, 135 with the overlay material 610 effectively increases the working electrodes' 130, 135 working area. The overlay material 610 may be selected to have particular desired electrical, chemical and physical properties. In particular, the selection of the overlay material 610 can be used to increase or decrease the current that flows through the working electrodes 130, 135.

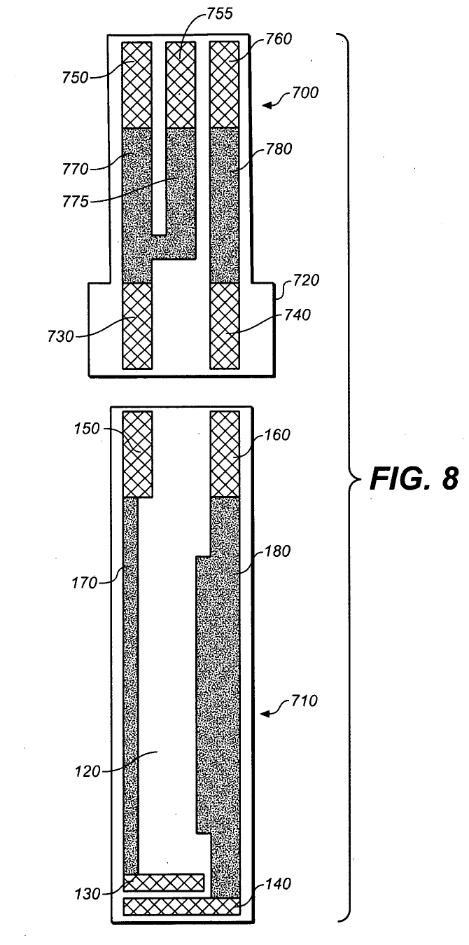

FIG. 8 shows an adapter 700 according to a preferred embodiment that, when in use, sits between a prior art test strip 710 having a single working electrode 130, working link 170 and working connector 150, and a multi-input meter (not shown). The adapter 700 is provided with a working electrode 730 and a reference electrode 740 that are configured to contact and form an electrical coupling with the working and reference connectors 150, 160 of the test strip 710, respectively. The single working electrode 730 of the adapter 700 is electrically coupled by a pair of working links 770, 775 to two working connectors 750, 755 that are configured to interface with the working sensor inputs of the meter. The reference electrode 740 of the adapter 700 is electrically coupled by a reference link 780 to the adapter's 700 reference connector 760, which is configured to interface with a reference connector on the meter. Preferably, the electrodes 730, 740 of the adapter 700 engage the connectors 150, 160 of the test strip 710 to releasably secure the adapter 700 to the test strip 710 during use. Once connected, the test strip 710 and adapter 700 function in the same manner as the test strip 300 of FIG. 3.

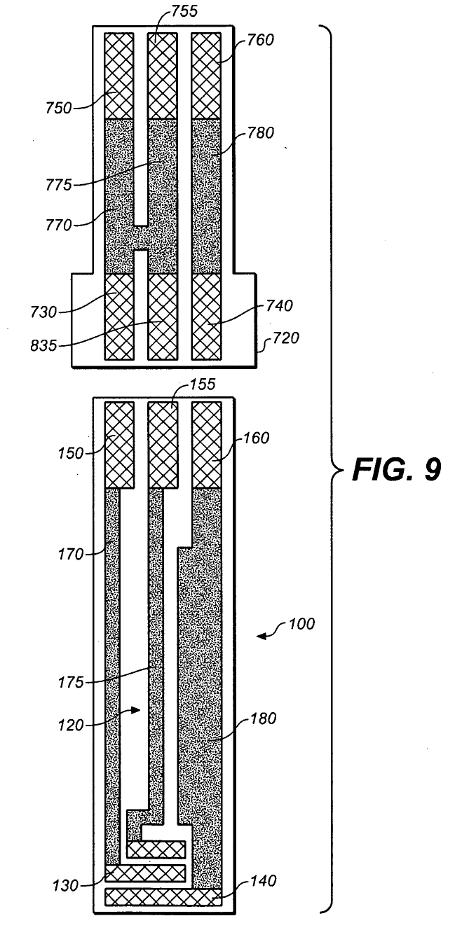

FIG. 9 shows a variation on the adapter 700 of FIG. 8. The adapter 800 of FIG. 9 is for use with the prior art test strip 100 of FIG. 1, which has two working electrodes 130, 135, each connected to a different one of two working connectors 150, 155 by separate working links 170, 175. The adapter 800 therefore includes two working electrodes 730, 835 that are configured to contact and form electrical couplings with the working connectors 150, 155 of the test strip 100. Each of the working electrodes 730, 835 of the adapter 800 is electrically coupled to both of the working connectors 750, 755 of the adapter by the working links 770, 775 of the adapter 800.

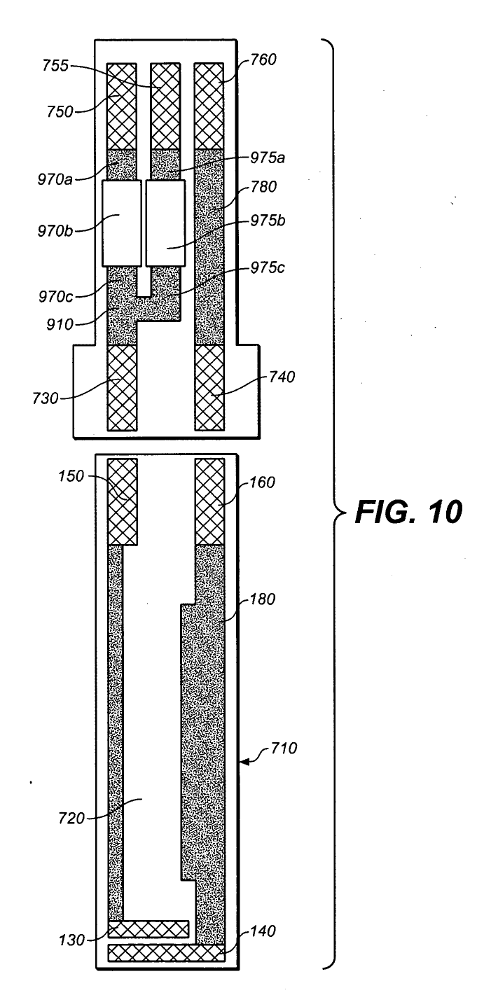

FIG. 10 shows another adapter 900 according to a preferred embodiment. The adapter 900 is similar to the adapter 700 of FIG. 8, except that the working links 970, 975 are split links that are each divided into three working link portions 970a-c, 975a-c. The split links 970, 975 may be divided into other numbers of portions; however, three is preferred. Although FIG. 10 shows two split working links 970, 975, other numbers of working links may be used, not all of which need be split links.

The split links 970, 975 of FIG. 10 each comprise a first link portion 970a, 975a and a third link portion 970c, 975c. Each first portion 970a, 975a is coupled to a working connector 750, 755 of the adapter 900 and each of the third portions 970c, 975c is coupled to the working electrode 730 of the adapter 900 at a junction 910. The first and third portions 970a, 975a, 970c, 975c of each link are separated by a gap, are preferably made of the same material and are preferably screen printed onto the substrate 720.

The adapter 900 of FIG. 10, less the second link portions 970b, 975b may be the adapter 700 of FIG. 8 with a discontinuity formed in each of the working links 770, 775 to define the first and third link portions 970a, 975a, 970c, 975c. These discontinuities may be formed by laser ablating, cutting, drilling or abrading the working links 770, 775, or by any other suitable process.

Each of the split links 970, 975 further includes a second link portion 970b, 975b that at least partially overlays the first and third link portions 970a, 975a, 970c, 975c and bridges the gap separating the first and third link portions. The second link portions 970b, 975b are preferably screen printed onto the adapter 900, but may be applied by hand painting or other suitable methods. The second link portions 970b, 975b may be made of the same material as the first and/or third link portions 970a, 975a, 970c, 975c.

However, the second link portions 970b, 975b are preferably formed from a material having a different resistivity to that of the first and third link portions 970a, 975a, 970c, 975c.

The resistivity of the material used to form the second link portions 970b, 975b of FIG. 10 may be varied across the working links 970, 975. Varying the second link portion 970b, 975b material and/or the second link portions' 970b, 975b dimensions and/or layout enables the resistivity of the working links 970, 975 to be weighted, in turn weighting the current available at each of the working connectors 750, 755.

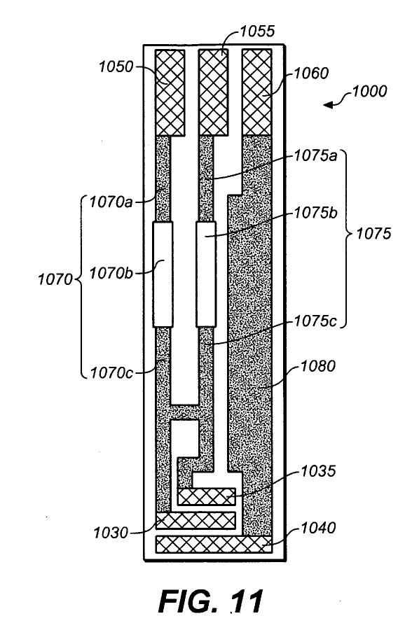

FIG. 11 shows a test strip 1000 according to a preferred embodiment. The test strip 1000 includes, on a substrate 1020, two working electrodes 1030, 1035 that are electrically coupled to two working connectors 1050, 1055 by two working links 1070, 1075. The test strip 1000 further includes a reference electrode 1040 that is electrically coupled to a reference connector 1060 by a reference link 1080. The working links 1070, 1075 are both split links, each split link comprising a first link portion 1070a, 1075a coupled to a working connector 1050, 1055 and a third link portion 1070c, 1075c coupled to a working electrode 1030, 1035. Each first link portion 1070a, 1075a is spaced apart from the corresponding third link portions 1070c, 1075c by a gap and the third link portions 1070c, 1075c are intercoupled at a junction 1010. Second link portions 1070b, 1075b, at least partially overlay both the first and third link portions 1070a, 1075a, 1070c, 1075c of each of the split working links 1070, 1075 and bridge the gap between each working link's 1070, 1075 first and third portions 1070a, 1075a, 1070c, 1075c. The split working links 1070, 1075 of the test strip 1000 of FIG. 11 are formed in a similar manner to those of the adapter 900 of FIG. 10 and can be similarly used to adjust the resistance of the working links 1070, 1075 and the division of the total working electrode 1030, 1035 current between the working connectors 1050, 1055.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods within the scope of these claims and their equivalents be covered thereby.

1-67. (canceled)

68. A system for electrochemically measuring an analyte in a sample material, the system comprising:
a strip comprising:
a reference electrode and a working electrode; a reference connector, a first working connector, and second working connector for interfacing the strip to the measuring device;
a reference link configured to electrically couple the reference electrode to the reference connector;
a first working link configured to electrically couple the working electrode to the first working connector, and
a second working link configured to electrically couple to the working electrode to the second working connector, and
a meter comprising:
a first test voltage circuit capable of applying a first test voltage between the first working connector and the reference connector;
a second test voltage circuit capable of applying a second test voltage between the second working connector and the reference connector;
a current measurement circuit capable of measuring a first test current between the first working connector and the reference connector and a second test current between the second connector and the reference connector.

69. The system of claim 68, wherein the first working connector and the second working connector are electrically coupled to form a shunt resistance,

70. The system of claim 69, wherein:
a shunt current flows between the first working connector and the second working connector, and
said shunt resistance is configured to cause the shunt current to be less than a pre-determined threshold.

71. The system of claim 68, wherein the shunt current is less than 100 nA.

72. The system of claim 68, wherein a resistance of the first working link is configured so that a voltage drop between the first working connector and the working electrode is less than 20% of the first test voltage.

73. (canceled)

74. An adapter comprising:
a substrate;
at least three electrical connectors disposed on the substrate; and
two electrodes coupled to the at least three electrical connectors and capable of electrically coupling with respective two electrical connectors of a test strip.

75. A test strip system comprising:
an adapter having
a first substrate;
at least three electrical connectors disposed on the substrate; and
two linking electrodes disposed on the substrate, one of the linking electrodes being coupled to one of the at least three connectors and the other linking electrode being coupled to at least two connectors of the at least three connectors;
a test strip having
a second substrate;
two electrodes disposed on the second substrate; and
two connectors disposed on the second substrate, each of the two connectors capable of electrical coupling to the respective linking electrodes of the adapter.

76. (canceled)
